(19) United States
(12) Patent Application Publication
(10) Pub. No.: US 2026/0023897 A1
(43) Pub. Date: Jan. 22, 2026

(54) METHOD AND SYSTEM FOR MODELING CHEMICAL MECHANICAL POLISHING

(71) Applicant: SAMSUNG ELECTRONICS CO., LTD., Suwon-si (KR)

(72) Inventors: Byungseon Choi, Suwon-si (KR); Bogyeong Kang, Suwon-si (KR); Jinuk Byun, Suwon-si (KR); Younggu Kim, Suwon-si (KR); Kihyun Park, Suwon-si (KR); Seunghoon Choi, Suwon-si (KR); Jaemyung Choe, Suwon-si (KR); Hyungho Choi, Suwon-si (KR)

(21) Appl. No.: 19/016,552

(22) Filed: Jan. 10, 2025

(30) Foreign Application Priority Data
Jul. 17, 2024 (KR) 10-2024-0094614

(51) Int. Cl. G06F 30/27; H01L 21/306

(52) U.S. Cl. CPC G06F 30/27; H01L 21/30625

(57) ABSTRACT

Methods of modeling chemical mechanical polishing applied to a wafer according to a recipe are provided. In one aspect, the method includes providing recipe data defining the recipe to a first model trained by recipe samples, obtaining a first removal amount from the first model, providing wafer data defining the wafer and the recipe data to a second model trained by the recipe samples and wafer samples, obtaining a second removal amount from the second model, and estimating a removal amount of the wafer generated by the chemical mechanical polishing, based on the first removal amount and the second removal amount.

### CROSS-REFERENCE TO RELATED APPLICATION

This application claims priority under 35 U.S.C. § 119 to Korean Patent Application No. 10-2024-0094614, filed on Jul. 17, 2024, in the Korean Intellectual Property office, the disclosure of which is incorporated by reference herein in its entirety.

### BACKGROUND

Semiconductor processes include various sub-processes for manufacturing integrated circuits. Parameters performing the sub-processes may be defined to obtain a desired result. For example, a polishing process may be performed on a wafer on which dies are formed, and the parameters of the polishing process may be defined to uniformly remove a desired amount of a layer material from the wafer. For high degree of integration and/or performance, the size of devices included in the integrated circuit may be reduced, the structure of the integrated circuit may be complicated, and the materials constituting the devices may be changed. Accordingly, the complexity of the sub-processes may increase and therefore may make it difficult to accurately define the parameters of the sub-processes.

### SUMMARY

The present disclosure provides a method and system for accurately estimating a removal amount by modeling chemical mechanical polishing (CMP), and based on the estimated removal amount, providing parameters required for the chemical mechanical polishing.

According to an aspect of the present disclosure, a method of modeling chemical mechanical polishing applied to a wafer is provided according to a recipe including providing recipe data defining the recipe to a first model trained by recipe samples, obtaining a first removal amount from the first model, providing wafer data defining the wafer and the recipe data to a second model trained by the recipe samples and wafer samples, obtaining a second removal amount from the second model, and estimating a removal amount of the wafer generated by the chemical mechanical polishing, based on the first removal amount and the second removal amount.

According to another aspect of the present disclosure, a system is provided for modeling chemical mechanical polishing applied to a wafer according to a recipe including a non-transitory storage medium configured to store instructions, and at least one processor configured to access the non-transitory storage medium, wherein the at least one processor is configured to, by executing the instructions, provide recipe data defining the recipe to a first model trained by recipe samples, obtain a first removal amount from the first model, provide wafer data defining the wafer and the recipe data to a second model trained by the recipe samples and wafer samples, obtain a second removal amount from the second model, and based on the first removal amount and the second removal amount, estimate a removal amount of the wafer generated by the chemical mechanical polishing.

According to another aspect of the present disclosure, a method of modeling chemical mechanical polishing applied to a wafer is provided according to a recipe including obtaining a recipe sample, a wafer sample, and a removal amount sample, training a first model based on the recipe sample and the removal amount sample, and training a second model based on the recipe sample, the wafer sample, the removal amount sample, and a first removal amount sample obtained from the trained first model, wherein the training of the second model trains the second model such that a sum of the first removal amount and a second removal amount obtained from the second model corresponds to the removal amount sample.

Implementations of the present disclosure can provide one or more of the following technical advantages. For example, modeling methods and systems based on a CMP model according to the present disclosure can be employed to determine a polishing recipe that allows a CMP apparatus to precisely remove a specified amount of materials from a target wafer. The CMP model can include a first model based on the Preston's equation, which takes into account a relative velocity between a pad and the target wafer, pressure on the target wafer, and process environmental factors (e.g., slurry) to estimate the removal amount. Additionally, the CMP model can include a second model that accounts for other factors not covered by the Preston's equation, such as wafer conditions (e.g., a thickness profile of the target wafer). Therefore, a more accurate estimation of the CMP removal amount can be obtained with the comprehensive modelling methods provided in the present disclosure. The CMP model can also output a suitable CMP recipe that enables the CMP apparatus to achieve the desired material removal from the wafer more effectively.

### BRIEF DESCRIPTION OF THE DRAWINGS

Implementations will be more clearly understood from the following detailed description taken in conjunction with the accompanying drawings in which:

FIG. 1 is a diagram of an example of a sub-process;

FIG. 2 is a diagram of an example modeling of chemical mechanical polishing;

FIG. 3 is a diagram of an example chemical mechanical polishing model;

FIG. 4 is a diagram of an example of a Preston equation-based model;

FIG. 5 is a diagram of an example of a search recipe;

FIG. 6 is a flowchart of an example method of modeling chemical mechanical polishing;

FIG. 7 is a flowchart of an example method of modeling chemical mechanical polishing;

FIG. 8 is a flowchart of an example method of modeling chemical mechanical polishing;

FIG. 9 is a graph of an example of a result of modeling chemical mechanical polishing;

FIG. 10 is a flowchart of an example method of modeling chemical mechanical polishing;

FIG. 11 is a flowchart of an example method of modeling chemical mechanical polishing;

FIG. 12 is a flowchart of an example method of modeling chemical mechanical polishing;

FIG. 13 is a block diagram of an example computing system; and

FIG. 14 is a block diagram of an example system.

### DETAILED DESCRIPTION

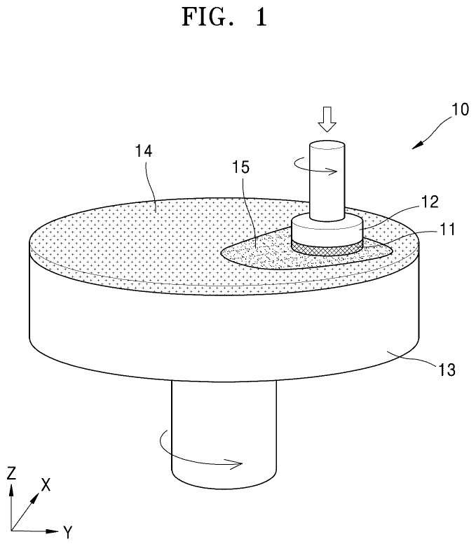

FIG. 1 is a diagram of an example of a sub-process according to some implementations. For example, FIG. 1 illustrates an example of chemical mechanical polishing (CMP) 10 as a sub-process included in a semiconductor process. The semiconductor process for manufacturing an integrated circuit may include a series of sub-processes, and a wafer 11 may be processed by using the series of sub-processes. For example, a front-end-of-line (FEOL) may include planarizing and cleaning a wafer, forming a trench, forming a well, forming a gate electrode, and forming a source and a drain, and by using the FEOL, individual devices, for example, a transistor, a capacitor, a resistor, or the like may be formed on a substrate. In addition, a back-end-of-line (BEOL) may include, for example, silicidating a gate region, a source region, and a drain region, adding a dielectric material, planarizing, forming a hole, adding a metal layer, forming a via, forming a passivation layer, or the like, and by using the BEOL, individual devices, for example, a transistor, a capacitor, a resistor, or the like may be connected to each other. In some implementations, a middle-end-of-line (MEOL) may be performed between the FEOL and the BEOL, and contacts may be formed on individual devices. A plurality of dies may be separated from the wafer 11, each of the plurality of dies may be packaged in a semiconductor package, and may be used as components of various applications.

As one of the sub-processes included in the semiconductor process, the CMP 10 may be performed to remove a desired amount of layer material from the wafer 11. As illustrated in FIG. 1, in the CMP 10, the wafer 11 may be attached to a head 12. The head 12 may rotate with respect to a Z axis as the center and apply pressure to the wafer 11 in a −Z direction. A pad 14 may be attached onto a platen 13, and the platen 13 may rotate with respect to the Z axis as the center. A slurry 15 may be applied on the pad 14, and the wafer 11 may be arranged on the slurry 15. Accordingly, a surface of the wafer 11 exposed in the −Z axis direction may be polished.

The performance of the CMP 10 may be evaluated by a surface flatness of the wafer 11 as a resultant product, that is, a profile of the wafer 11. For example, the profile may represent a thickness of the wafer 11 (or the layer material) along a line crossing the center of the wafer 11. Herein, the profile of the wafer 11 may be simply referred to as a profile. The wafer 11 may include a plurality of dies (or chips), and the poor surface flatness may cause a fatal effect on the yield as well as the performance of the integrated circuit.

Preston's equation may define a removal rate (RR) as shown in Equation 1 below, in the CMP 10.

$$R R = {K}_{p} \times P \times V \qquad [ Equation 1 ]$$

In Equation 1, P indicates the pressure applied to the wafer 11 in the −Z axis direction via the head 12, V indicates a relative velocity between the head 12 and the pad 14, and Kₚ indicates a Preston's coefficient (which may be referred to herein as an environment coefficient) that defines a process environment including the slurry 15. In other words, in the CMP 10, the removal rate RR of the wafer 11 may be proportional to the pressure P and the relative velocity V.

For high degree of integration and/or performance, the devices included in the integrated circuit may have reduced sizes and complex structures, and the materials constituting the devices may be changed. As a result, the complexity of the CMP 10 may increase, and the amount of layer material removed from the wafer 11 by the CMP 10, that is, a removal amount, may be affected by various parameters as well as the pressure P and the relative velocity V described above, and may not be simply determined by the Preston's equation. Accordingly, it may not be easy to determine a recipe of the CMP 10, that is, parameters defining the CMP 10. Herein, the removal amount may be referred to as the removal amount causing the profile of the wafer 11 by using the CMP 10, and may represent, for example, the amount removed along a line intersecting the center of the wafer 11.

As described below with reference to the drawings, the CMP 10 may be modeled considering various parameters, and the removal amount generated by the CMP 10 may be accurately estimated. Accordingly, the recipe of the CMP 10 for a desired profile of the wafer 11 may be easily derived, and the cost required for designing the CMP 10 may be reduced. In addition, the performance and reliability of integrated circuits manufactured by a semiconductor process including the CMP 10 designed according to the recipe may be improved.

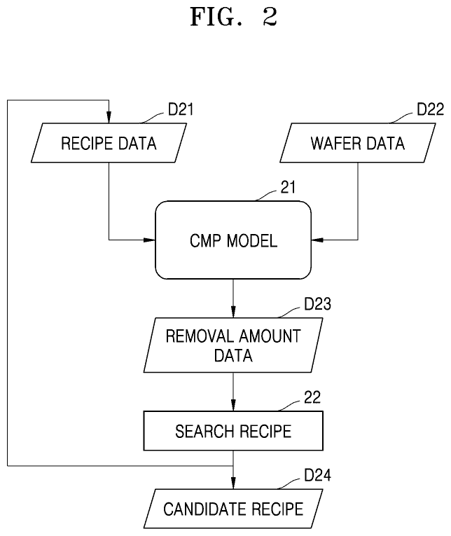

FIG. 2 is a diagram of modeling of CMP according to some implementations. As described above with reference to FIG. 1, the CMP 10 may be modeled as a CMP model 21, and accordingly, a removal amount corresponding to a given recipe and wafer may be estimated. In addition, the recipe, that is, a candidate recipe D24, that provides a desired removal amount by using the CMP model 21, may be provided. Hereinafter, FIG. 2 is described with reference to FIG. 1.

Referring to FIG. 2, recipe data D21 and wafer data D22 may be provided to the CMP model 21. The recipe data D21 may be referred to as data defining the recipe of the CMP 10. For example, the recipe data D21 may include values of parameters of the CMP 10, and the CMP 10 may be defined by parameters having values included in the recipe data D21. The wafer data D22 may be referred to as data defining the wafer 11 provided for the CMP 10. For example, the wafer data D22 may include values of the measured thickness of the layer material along a diameter of the wafer 11, that is, the profile of the wafer 11 before the CMP 10.

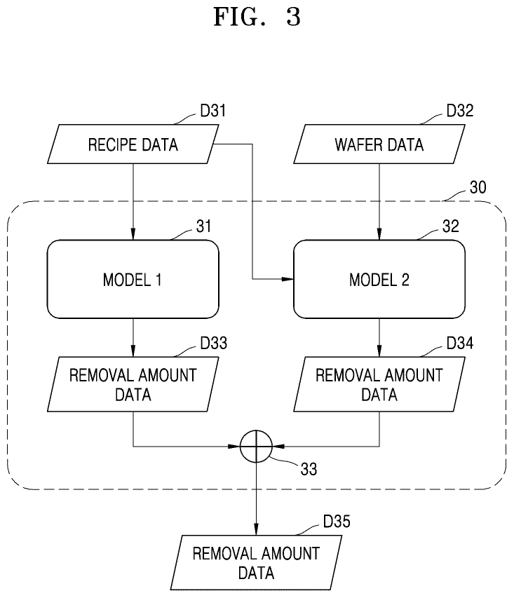

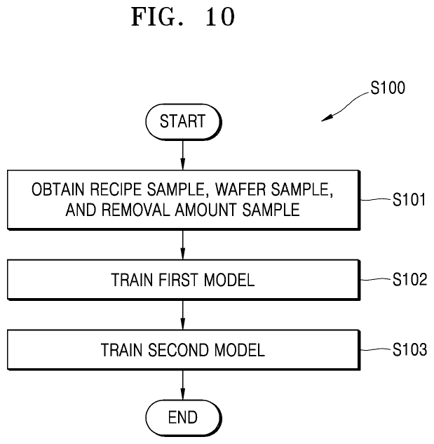

The CMP model 21 may generate removal amount data D23 from the recipe data D21 and the wafer data D22 based on machine learning. For example, as described below with reference to FIG. 10, a removal amount sample may be obtained by applying recipe samples and wafer samples to the CMP 10, and the CMP model 21 may have been trained by the recipe samples, the wafer samples, and the removal amount samples. As will be described below with reference to FIG. 3, the CMP model 21 may include a model based on the Preston's equation and a model based on hidden components, and the removal amount data D23 may represent a removal amount generated by the CMP 10 with high accuracy. An example of the CMP model 21 is to be described below with reference to FIG. 3.

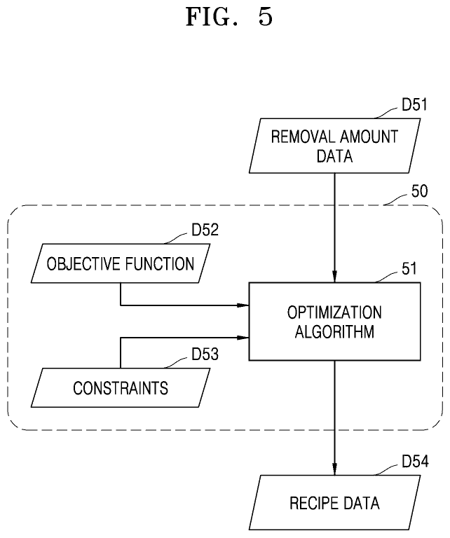

A search recipe 22 for a recipe that provides a desired removal amount may be performed. As illustrated in FIG. 2, the search recipe 22 may be performed based on the removal amount data D23 provided by the CMP model 21. The search recipe 22 may generate the recipe data D21 based on the removal amount data D23 to provide the generated recipe data D21 to the CMP model 21, and may determine a recipe that provides a desired removal amount, that is, the candidate recipe D24. The CMP 10 may be designed according to the candidate recipe D24, and the wafer 11 having a desired profile may be manufactured by using the CMP 10. An example of the search recipe 22 is to be described below with reference to FIG. 5.

In some implementations, modeling of the CMP 10 may be implemented by an arbitrary computing system. For example, each of the blocks illustrated in the diagrams herein may correspond to hardware, software, or a combination of hardware and software, which are included in a computing system. In some implementations, the hardware may include at least one of a programmable component, such as a central processing unit (CPU), a digital signal processor (DSP), a graphics processing unit (GPU), and a natural processing unit (NPU), a reconfigurable component such as a field programmable gate array (FPGA), and a component providing fixed functions such as an intellectual property (IP) block. In some implementations, software may include at least one of a series of instructions executable by a programmable component and code transformable into a series of instructions by a compiler or the like, and may be stored in a non-transitory storage medium.

FIG. 3 is a diagram of a CMP model 30 according to some implementations. For example, FIG. 3 illustrates an example of the CMP model 21 in FIG. 2. As described above with reference to FIG. 2, the CMP model 30 may generate removal amount data D35 from recipe data D31 and wafer data D32. As illustrated in FIG. 3, the CMP model 30 may include a first model 31 and a second model 32. Descriptions to be given with reference to FIG. 3 that are substantially the same as those given with reference to FIG. 2 are omitted.

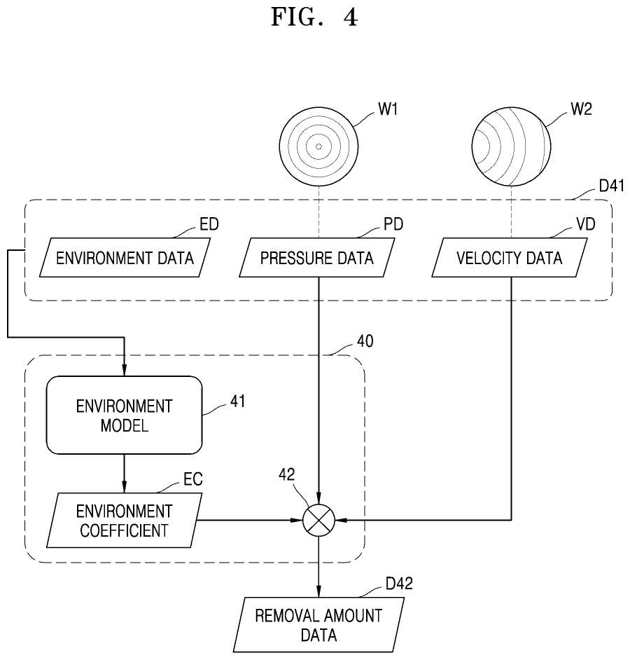

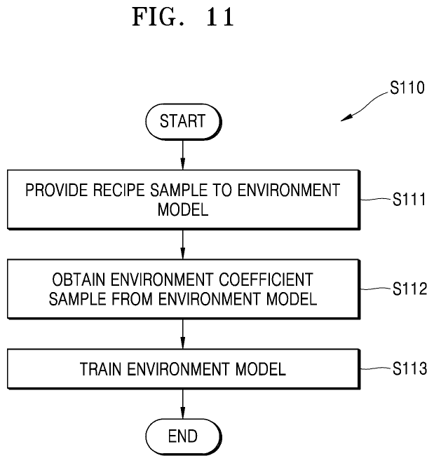

The first model 31 may generate first removal amount data D33 from the recipe data D31. For example, as to be described below with reference to FIG. 11, the first model 31 may have been trained by recipe samples and removal amount samples corresponding to the recipe samples. As will be described below with reference to FIG. 4, the first model 31 may include a model for inferring Preston's coefficients, that is, environment coefficients, and may generate the first removal amount data D33 representing a removal amount based on Preston's equation. Herein, the first model 31 may be referred to as a Preston's equation-based model, and the removal amount represented by the first removal amount data D33 may be referred to as a first removal amount. An example of the first model 31 is to be described below with reference to FIG. 4.

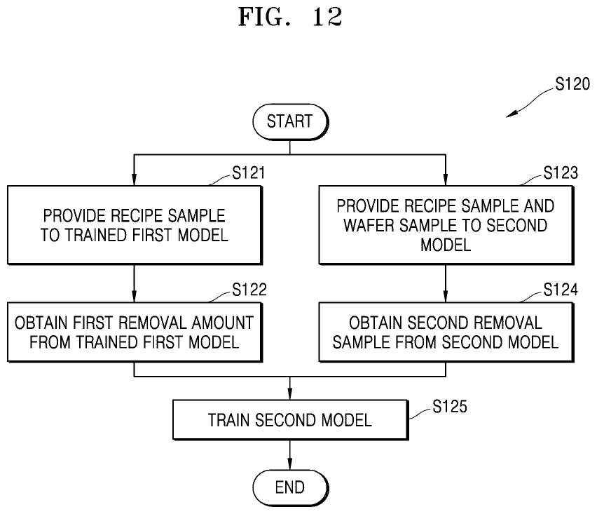

The second model 32 may generate second removal amount data D34 from the recipe data D31 and the wafer data D32. For example, as will be described below with reference to FIG. 12, the second model 32 may be in a state in which the second model 32 has been trained by the recipe samples, the wafer samples, output samples of the trained first model 31 (that is, the first removal amount samples), and the removal amount samples. As described above with reference to FIG. 1, the CMP 10 may not be interpreted only by using the Preston's equation, and the second model 32 may infer components that are not interpreted by the Preston's equation. Herein, the second model 32 may be referred to as a hidden components model, and the removal amount represented by the second removal amount data D34 may be referred to as a second removal amount.

The CMP model 30 may include an adder 33, and the adder 33 may generate the removal amount data D35 by adding the first removal amount represented by the first removal amount data D33 and the second removal amount represented by the second removal amount data D34. In other words, a removal amount represented by the removal amount data D35 may include the first removal amount inferred based on the Preston's equation and the second removal amount obtained by the hidden components. Accordingly, the CMP model 30 may accurately estimate a removal amount generated by the CMP 10 from the recipe data D31 and the wafer data D32 that are given.

Each of the first model 31 and the second model 32 may include a machine learning model, and the machine learning model may have an arbitrary structure in which training is possible by using, for example, backpropagation, a Lagrange multiplier method, or the like and by using sample data or training data. For example, the machine learning model may include an artificial neural network, a decision tree, a support vector machine, and/or a Bayesian network, etc. Hereinafter, the machine learning model is to be described mainly with reference to the artificial neural network, however, the implementations are not limited thereto. The artificial neural network may include, as a non-limiting example, a convolution neural network (CNN), a region (R)-based CNN (R-CNN), a region proposal network (RPN), a recurrent neural network (RNN), a stacking (S)-based deep neural network (DNN) (S-DNN), a state(S)-space(S) DNN (S-SDNN), a deconvolution network, a deep belief network (DBN), a fully convolutional network, a long short-term memory (LSTM) network, etc.

FIG. 4 is a diagram of an example of a Preston's equation-based model, according to some implementations. For example, FIG. 4 illustrates a first model 40 as an example of the first model 31 in FIG. 3. As described above with reference to FIG. 3, the first model 40 may generate first removal amount data D42 from recipe data D41. Hereinafter, FIG. 4 is described with reference to FIG. 1.

Referring to FIG. 4, the recipe data D41 may include environment data ED, pressure data PD, and velocity data VD. The environment data ED may define parameters excluding the pressure data PD and the velocity data VD to be described below with reference to the CMP 10. For example, the environment data ED may include characteristics and temperature, or the like of the slurry 15 applied on the pad 14. The pressure data PD may define pressure applied to the wafer 11 by using the head 12. In some implementations, the head 12 may apply non-uniform pressures, that is, different pressures, for each region. For example, as illustrated in a distribution W1 in FIG. 4, pressure depending on a distance from the center of the wafer 11 may be applied. The velocity data VD may define a relative velocity between the pad 14 and the head 12. For example, a surface of the wafer 11 may be in parallel with a plane including the X-axis and the Y-axis in FIG. 1, and the relative velocity may be defined as a function fᵥ as shown in Equation 2 below.

$${f}_{v} ( x , y , R P {M}_{p} , R P {M}_{h} , {r}_{cc} ) = \frac{2 π}{60} \sqrt{{( ( R P {M}_{h} - R P {M}_{p} ) \times y )}^{2} + {( ( R P {M}_{h} - R P {M}_{p} ) \times x - ( R P {M}_{p} \times {r}_{cc} ) )}^{2}} \qquad [ Equation 2 ]$$

In Equation 2, x and y may mean the coordinates of the Cartesian coordinate system, RPMₚ may mean the revolutions per minute of the pad 14, PRMₕ may mean the revolutions per minute of the head 12, and r_{cc} may mean the distance between the center point of the pad 14 and the center point of the head 12. In some implementations, as illustrated in a distribution W2 in FIG. 4, the relative velocity may have a distribution that depends on a distance from the center of the pad 14.

The first model 40 may include an environment model 41 and a multiplier 42. Because the pressure data PD and the velocity data VD are known to a user as settable parameters, a Preston's coefficient, that is, the environment coefficient, may be required to calculate the removal rate by using the Preston's equation defined as Equation 1. The environment model 41 may generate an environment coefficient EC from the recipe data D41 including the environment data ED, the pressure data PD, and the velocity data VD. For example, as to be described below with reference to FIG. 11, the environment model 41 may have been trained by recipe samples and removal amount samples. The multiplier 42 may generate the first removal amount data D42 by multiplying the environment coefficient EC, the pressure represented by the pressure data PD, and the relative velocity represented by the velocity data VD. Because the first removal amount represented by the first removal amount data D42 is a positive number, the environment coefficient may also be a positive number, and in some implementations, the environment model 41 may include an activation function having a positive value as an output. For example, the environment model 41 may include an activation function, such as a rectified linear unit (ReLU) and a Sigmoid function.

FIG. 5 is a diagram of a search recipe 50 according to some implementations. As described above with reference to FIG. 2, the search recipe 50 may generate recipe data D54 from removal amount data D51 provided by the CMP model 21, and the recipe data D54 may be provided again to the CMP model 21. When the recipe data D54 provides a desired profile, the search recipe 50 may determine a recipe defined by the recipe data D54 as a candidate recipe. Hereinafter, FIG. 5 is described with reference to FIG. 1.

As illustrated in FIG. 5, the search recipe 50 may include an optimization algorithm 51. The optimization algorithm 51 may generate the recipe data D54 from the removal amount data D51 based on an objective function D52 and constraints D53, which are predefined. For example, the optimization algorithm 51 may generate the recipe data D54 that minimizes a value of the objective function D52 while satisfying the constraints D53. In some implementations, the CMP may be aimed at minimizing non-uniformity (NU) defined by Equation 3 below.

$$N U ( \% ) = \frac{{S}_{RA}}{R {A}_{avg}} \times 100 or \frac{max ( R A ) - min ( R A )}{R {A}_{Avg}} \times 100 \qquad [ Equation 3 ]$$

In Equation 3, RA may mean the removal amount, RA_{avg} may mean an average of the removal amount, S_{RA} may mean a standard deviation of the removal amount, and max(RA) and min(RA) may respectively mean the maximum value and the minimum value of the removal amount. Because the NU defined by Equation 3 decreases as the denominator, that is, the average of the removal amount, increases, when Equation 3 itself is used as an objective function, the optimization algorithm 51 may perform optimization in a direction of excessive polishing of the wafer 11. To prevent the excessive polishing, two objective functions, that is, a first objective function fₒ₁ and a second objective function fₒ₂, may be defined as shown in Equation 4 below.

$${f}_{01} ( R {A}_{est} ) = s ( R {A}_{est} ) or max ( R {A}_{est} ) - min ( R {A}_{est} ) \qquad [ Equation 4 ]$$

$${f}_{02} ( R {A}_{est} ) = \sqrt{\sum {( R {A}_{est} - R {A}_{tar} )}^{2}}$$

In Equation 4, RAₑₛₜ may mean an estimated removal amount, and may be defined by the removal amount data D51 provided by the CMP model 21. RAₜₐᵣ may mean the desired removal amount (or the profile) by using the CMP. As shown in Equation 4, the first objective function fₒ₁ may be based on the distribution of the estimated removal amount, and the second objective function fₒ₂ may be based on the difference between the estimated removal amount and a target removal amount. The optimization algorithm 51 may search for the removal amount that minimizes the first objective function fₒ₁ and the second objective function fₒ₂ and a recipe corresponding to the removal amount.

The constraints D53 may be defined for stability of the CMP. For example, the constraints D53 may be defined such that the recipe searched for by using the optimization algorithm 51 becomes a real recipe applicable to the actual CMP. In some implementations, the constraints D53 may be defined based on a ratio of the removal amount to hidden components. For example, a first constraint C₁ and a second constraint C₂ may be defined as shown in Equation 5 below.

$${C}_{1} = \frac{\sum \vert R {A}_{2} \vert}{\sum R {A}_{est}} \geq {THR}_{1} \qquad [ Equation 5 ]$$

$${C}_{2} = \frac{\sum \vert R {A}_{2} \vert}{\sum R {A}_{est}} \leq {THR}_{2}$$

In Equation 5, RA₂ may mean the second removal amount, and may be defined by the second removal amount data D34 provided by the second model 32 of FIG. 3. A first threshold THR₁ and a second threshold THR₂ may be predefined constants. Accordingly, while a recipe in which a ratio of hidden components satisfies the first threshold THR₁ or more may be searched for by the first constraint C₁, a recipe in which a ratio of hidden components satisfies the second threshold THR₂ or less may be searched for by the second constraint C₂. In some implementations, the constraints D53 may include only one of the first constraint C₁ and the second constraint C₂. In some implementations, the constraints D53 may include both the first constraint C₁ and the second constraint C₂ when the first threshold THR₁ is less than or equal to the second threshold THR₂.

The optimization algorithm 51 may include an arbitrary optimization algorithm that uses the given CMP model 21, provides multi-purpose optimization included in the objective function D52 while satisfying the constraints D53, and searches for the recipe. For example, the optimization algorithm 51 may also include a genetic algorithm such as non-dominated sorting genetic algorithm (NSGA2), and may also include a population-based algorithm such as a particle swarm optimization.

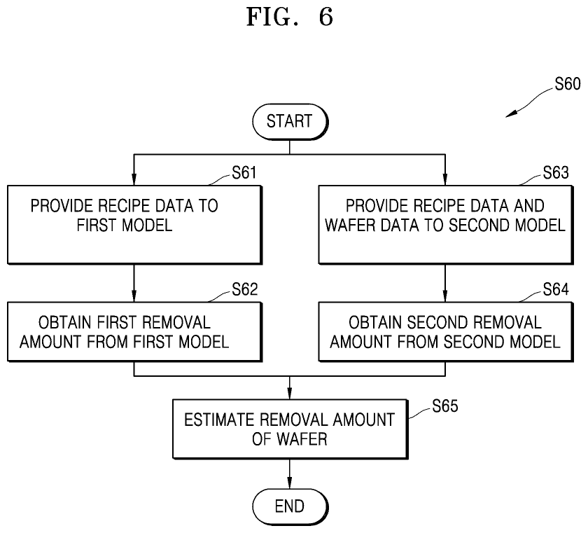

FIG. 6 is a flowchart of method S60 of modeling the CMP, according to some implementations. As illustrated in FIG. 6, method S60 of modeling the CMP may include a plurality of operations S61 through S65. In some implementations, method S60 of FIG. 6 may be performed by using the CMP model 30 in FIG. 3. Hereinafter, FIG. 6 is described with reference to FIGS. 1 and 3.

Referring to FIG. 6, in operation S61, the recipe data D31 may be provided to the first model 31. As described above with reference to the drawings, the first model 31, as a Preston's equation-based model, may have been trained by the recipe samples and the removal amount samples. The recipe data D31 may include parameters defining the CMP 10. For example, as described above with reference to FIG. 4, the recipe data D31 may include parameters representing the process environment, such as the pressure applied to the wafer 11 by the head 12, the relative velocity between the head 12 and the pad 14, and the slurry 15.

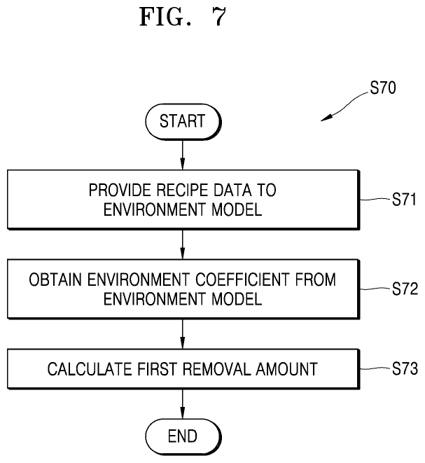

In operation S62, the first removal amount may be obtained from the first model 31. For example, the first model 31 may generate the first removal amount data D33 from the recipe data D31 provided in operation S61, and the first removal amount data D33 may represent the first removal amount. As described above with reference to the drawings, the first removal amount may correspond to the removal amount estimated based on the Preston's equation. An example of operation S62 is to be described below with reference to FIG. 7.

In operation S63, the recipe data D31 and the wafer data D32 may be provided to the second model 32. As described above with reference to the drawings, the second model 32, as a model based on hidden components, may have been trained by the wafer samples as well as the recipe samples and the removal amount samples. As described above, while the recipe data D31 includes parameters defining the CMP 10, the wafer data D32 may include parameters defining a state of the wafer 11. For example, the wafer data D32 may include the profile of the wafer 11 before the CMP 10 is performed.

In operation S64, the second removal amount may be obtained from the second model 32. For example, the second model 32 may generate the second removal amount data D34 from the recipe data D31 and the wafer data D32 provided in operation S63, and the second removal amount data D34 may represent the second removal amount. As described above with reference to the drawings, the second removal amount may correspond to the removal amount that is not interpreted by the Preston's equation, that is, the removal amount based on the hidden components.

In operation S65, the removal amount of the wafer 11 may be estimated. For example, the CMP model 30 may include the adder 33, the adder 33 may generate the removal amount data D35 by adding the first removal amount obtained in operation S62 and the second removal amount obtained in operation S64, and the removal amount data D35 may represent the estimated removal amount. Accordingly, the estimated removal amount may include the first removal amount based on the Preston's equation and the second removal amount based on the hidden components.

FIG. 7 is a flowchart of method S70 of modeling the CMP, according to some implementations. For example, the flowchart of FIG. 7 illustrates an example of operation S62 in FIG. 6. As described above with reference to FIG. 6, in method S70 of FIG. 7, the first removal amount may be obtained from the first model 31. As illustrated in FIG. 7, method S70 may include a plurality of operations S71 through S73. In some implementations, method S70 of FIG. 7 may be performed by using the first model 40 in FIG. 4. Hereinafter, FIG. 7 is described with reference to FIGS. 1 and 4.

Referring to FIG. 7, in operation S71, the recipe data D41 may be provided to the environment model 41, and in operation S72, the environment coefficient EC may be obtained from the environment model 41. For example, as described above with reference to FIG. 4, the first model 40 may include the environment model 41, and the environment model 41 may have been trained by the recipe samples and the removal amount samples, to generate the Preston's coefficient corresponding to the recipe data D41, that is, the environment coefficient EC.

In operation S73, the first removal amount may be calculated. For example, the first model 40 may include the multiplier 42, and the multiplier 42 may calculate the first removal amount by multiplying the pressure and the relative velocity extracted from the recipe data D41 by the environment coefficient EC obtained in operation S72, and may generate the first removal amount data D42 representing the first removal amount. As will be described below with reference to FIG. 11, the environment model 41 may be trained to reduce the difference between the first removal amount and the removal amount sample, and the trained environment model 41 may infer the environment coefficient EC from the recipe data D41.

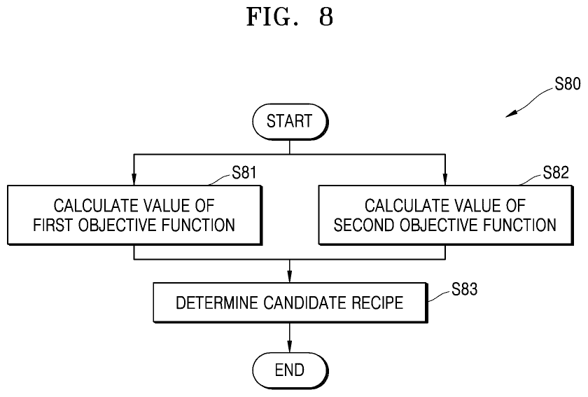

FIG. 8 is a flowchart of method S80 of modeling the CMP, according to some implementations. For example, the flowchart of FIG. 8 illustrates an example of the search recipe 22 in FIG. 2. As described above with reference to FIG. 2, method S80 of FIG. 8 may search for the recipe data D21 that provides a desired removal amount by using the CMP model 21, and may determine the candidate recipe D24. As illustrated in FIG. 8, method S80 may include a plurality of operations S81 through S83. In some implementations, method S80 of FIG. 8 may be an example of the search recipe 50 in FIG. 5. Hereinafter, FIG. 8 is described with reference to FIG. 5.

Referring to FIG. 8, in operation S81, a value of a first objective function may be calculated. For example, the objective function D52 provided to the optimization algorithm 51 may include the first objective function based on a distribution of the removal amount. In some implementations, the first objective function may include a standard deviation of the estimated removal amount as shown in Equation 4, or a difference between the maximum value and the minimum value of the estimated removal amount. The optimization algorithm 51 may calculate a value of the first objective function corresponding to the estimated removal amount represented by the removal amount data D51, and the value of the first objective function may represent the distribution of the estimated removal amount.

In operation S82, a value of a second objective function may be calculated. For example, the objective function D52 provided to the optimization algorithm 51 may include the second objective function based on a difference between the removal amount and the target removal amount. In some implementations, the second objective function may be defined as a Euclidean distance between the estimated removal amount and the target removal amount, as shown in Equation 4. The optimization algorithm 51 may calculate the value of the second objective function corresponding to the removal amount data D51 and a predefined target removal amount, and the value of the second objective function may represent an error between the estimated removal amount and the target removal amount.

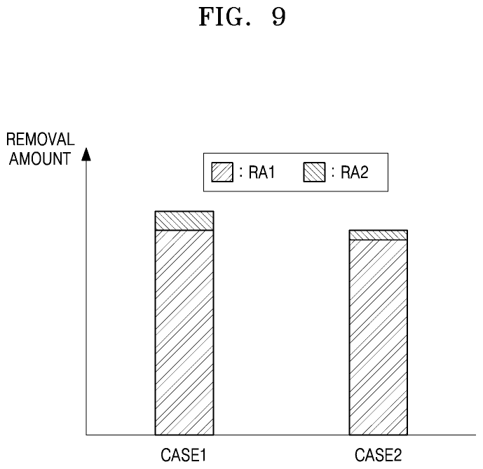

In operation S83, the candidate recipe may be determined. For example, the optimization algorithm 51 may generate the recipe data D54 to minimize the value of the first objective function calculated in operation S81 and the value of the second objective function calculated in operation S82, and the recipe data D54 may be provided to the CMP model 21. In addition, the constraints D53 may be provided to the optimization algorithm 51, and the optimization algorithm 51 may generate the recipe data D54 to satisfy the constraints D53. In some implementations, the constraints D53 may be defined based on a ratio of the removal amount to hidden components, as shown in Equation 5. A change in the estimated removal amount according to the constraints D53 is to be described below with reference to FIG. 9.

FIG. 9 is a graph of an example of a result of modeling the CMP, according to some implementations. For example, the graph in FIG. 9 illustrates the estimated removal amount in two cases. As illustrated in FIG. 9, the estimated removal amount may include a first removal amount RA1 based on the Preston's equation and a second removal amount RA2 due to hidden components.

In a first case CASE1, the optimization algorithm may search for a recipe without constraints defined based on the ratio of the removal amount due to hidden components as shown in Equation 5. In a second case CASE2, the optimization algorithm may search for a recipe according to defined constraints based on the ratio of the removal amount due to hidden components as shown in Equation 5. As illustrated in FIG. 9, the removal amount estimated in the first case CASE1 may include the second removal amount RA2 having a higher ratio than the removal amount estimated in the second case CASE2. In other words, the second removal amount RA2 may be limited in the second case CASE2 due to the constraints for limiting the estimation due to hidden components. The user may adjust the ratio of the second removal amount due to the hidden components by adjusting the desired thresholds of Equation 5.

FIG. 10 is a flowchart of method S100 of modeling the CMP, according to some implementations. For example, the flowchart of FIG. 10 illustrates a method of training the CMP model 21 of FIG. 2. As described above with reference to the drawings, the CMP model 21 may be trained by using the recipe samples, the wafer samples, and the removal amount samples. As illustrated in FIG. 10, method S100 may include a plurality of operations S101 through S103. In some implementations, using method S100 of FIG. 10 the CMP model 30 in FIG. 3 may be trained. Hereinafter, FIG. 10 is described with reference to FIG. 3.

Referring to FIG. 10, in operation S101, a recipe sample, a wafer sample, and a removal amount sample may be obtained. Sample data may be collected for training of the CMP model 30, and may be generated by performing the CMP. For example, the CMP may be performed by using the recipe sample and the wafer sample, and the removal amount sample, that is, a profile sample, may be obtained from a wafer that has undergone the CMP.

In operation S102, the first model 31 may be trained. For example, the first model 31 may be trained based on the recipe sample and the removal amount sample. The recipe sample may be provided to the first model 31, and the first model 31 may be trained such that the first removal amount generated by the first model 31 corresponds to the removal amount samples. As described above with reference to the drawings, the first model 31 may include a Preston's equation-based model, and unlike the second model 32 to be described below, the first model 31 may be trained independently from the wafer sample. An example of operation S102 is to be described below with reference to FIG. 11.

In operation S103, the second model 32 may be trained. For example, the second model 32 may be trained based on the recipe sample and the removal amount sample as well as the wafer sample. The recipe sample and the wafer sample may be provided to the second model 32, and the second model 32 may generate the second removal amount. The second model 32 may be trained based on not only the second removal amount but the first removal amount generated by the first model 31. As described above with reference to the drawings, the second model 32 may include a hidden components-based model, and unlike the first model 31 described above, the second model 32 may be trained on the wafer sample. An example of operation S103 is to be described below with reference to FIG. 12.

FIG. 11 is a flowchart of method S110 of modeling the CMP, according to some implementations. For example, the flowchart of FIG. 11 illustrates an example of operation S102 in FIG. 10. As described above with reference to FIG. 10, method S110 may train a first model, that is, a Preston's equation-based model. As illustrated in FIG. 11, method S110 may include a plurality of operations S111 through S113. In some implementations, method S110 may be performed by using the first model 40 in FIG. 4. Hereinafter, FIG. 11 is described with reference to FIG. 4.

Referring to FIG. 11, in operation S111, the recipe sample may be provided to the environment model 41, and in operation S112, an environment coefficient sample may be obtained from the environment model 41. For example, as described above with reference to FIG. 4, the first model 40 may include the environment model 41. The Preston's equation may require the Preston's coefficient, that is, the environment coefficient EC, as well as the pressure and the relative velocity, and may be trained to generate the Preston's coefficient, that is, the environment coefficient EC, corresponding to the recipe.

In operation S113, the environment model 41 may be trained. As described above, the environment model 41 may generate the environment coefficient sample corresponding to the recipe sample. The first removal amount sample based on the Preston's equation may be calculated as a product of the pressure and the relative velocity included in the environment coefficient sample and the recipe sample, and the environment model 41 may be trained to reduce the difference between the first removal amount sample and the removal amount sample. In some implementations, the environment model 41 may include an artificial neural network, and may be trained by backpropagation.

FIG. 12 is a flowchart of method S120 of modeling the CMP, according to some implementations. For example, the flowchart of FIG. 12 illustrates an example of operation S103 in FIG. 10. As described above with reference to FIG. 10, method S120 may train a second model, that is, a hidden components-based model. As illustrated in FIG. 12, method S120 may include a plurality of operations S121 through S125. In some implementations, method S120 may train the second model 32 in FIG. 3. Hereinafter, FIG. 12 is described with reference to FIG. 3.

Referring to FIG. 12, in operation S121, a recipe sample may be provided to the first model 31 that is trained, and in operation S122, the first removal amount sample may be obtained from the first model 31 that is trained. As described above with reference to FIG. 11, the first model 31 may include the environment model, and the environment model may be trained to generate the Preston's coefficient, that is, the environment coefficient, from a recipe. The second model 32 may be trained based on the first removal amount sample provided by the first model 31 including the trained environment model, that is, by the trained first model 31. Accordingly, the first model 31 may have been trained before the second model 32 is trained, while the second model 32 is being trained, the first model 31 may be fixed, and the parameters of the first model 31 may be unchanged.

In operation S123, the recipe sample and the wafer sample may be provided to the second model 32, and in operation S124, the second removal amount sample may be obtained from the second model 32. As described above with reference to the drawings, the second removal amount sample may correspond to the removal amount due to hidden components.

In operation S125, the second model 32 may be trained. For example, the first removal amount sample obtained in operation S122 and the second removal amount sample obtained in operation S124 may be added together, and the second model 32 may be trained, e.g., based on a loss function, to reduce the difference between the sum of the first removal amount and the second removal amount and the removal amount sample corresponding to the recipe sample and the wafer sample.

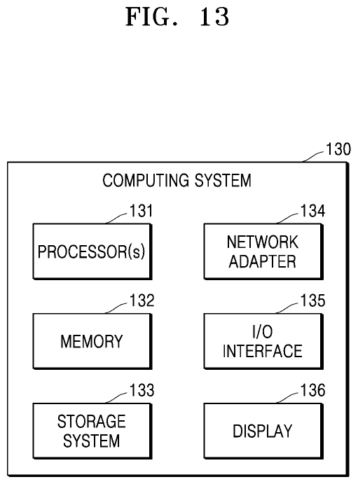

FIG. 13 is a block diagram illustrating a computing system 130 according to some implementations. In some implementations, the computing system 130 of FIG. 13 may perform training on the machine learning models used in the modeling of the CMP described above with reference to the drawings, and may be referred to as a CMP modeling system, a training system, etc.

The computing system 130 may indicate an arbitrary system including a general purpose or specific purpose computing system. For example, the computing system 130 may include a personal computer, a server computer, a laptop computer, a home appliance, etc. As illustrated in FIG. 13, the computing system 130 may include at least one processor 131, a memory 132, a storage system 133, a network adapter 134, an input/output (I/O) interface 135, and a display 136.

The at least one processor 131 may execute a program module including a computing system executable command. The program module may include routines, programs, objects, components, logic, data structures, or the like that perform a particular task or implement a particular abstract data type. The memory 132 may include a computing system-readable medium in the form of a volatile memory such as random-access memory (RAM). The at least one processor 131 may access the memory 132, and execute instructions loaded on the memory 132. The storage system 133 may non-transitorily store information, and include at least one program product including a program module configured to perform training on machine learning models for the modeling of the CMP described above with reference to the diagrams in some implementations. The program may include, as non-limiting examples, an operating system, at least one application, other program modules, and program data.

The network adapter 134 may provide access to a local area network (LAN), a wide area network (WAN), and/or a public network (for example, the Internet). The input/output interface 135 may provide a communication channel with a periphery device, such as a keyboard, a pointing device, and an audio system. The display 136 may output various pieces of information so that the user may identify various pieces of information.

In some implementations, the training of the machine learning models for the pattern clustering described above with reference to the diagrams may be implemented as a computing program product. The computing program product may include a non-transitory computer-readable medium (or storage medium) including computer-readable program instructions for allowing the at least one processor 131 to perform image processing and/or training of models. The computer-readable instruction may include, as a non-limiting example, an assembler instruction set architecture (ISA) instruction, a machine instruction, a machine-dependent instruction, microcode, a firmware instruction, state setting data, or source code or object code written in at least one programming language.

The computer-readable medium may include any type of medium capable of non-transitorily holding and storing instructions executed by at least one processor 131 or any instruction-executable device. The computer-readable medium may include an electronic storage device, a magnetic storage device, an optical storage device, an electromagnetic storage device, a semiconductor storage device, or any combination thereof, but is not limited thereto. For example, the computer-readable medium may include a portable computer diskette, a hard disc, RAM, ROM, electrically usable ROM (EEPROM), flash memory, static RAM (SRAM), a compact disc (CD), a digital versatile disc (DVD), a memory stick, a floppy disk, a mechanically encoded device such as a punch card, or any combination thereof.

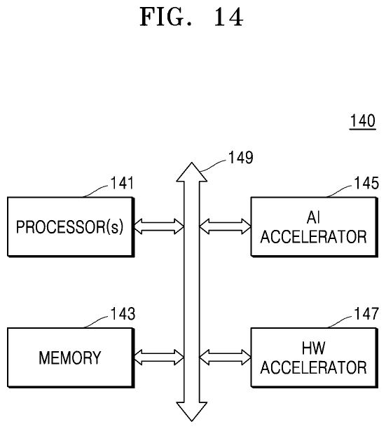

FIG. 14 is a block diagram of a system 140 according to some implementations. In some implementations, the modeling of the CMP according to some implementations may be performed in the system 140.

Referring to FIG. 14, the system 140 may include at least one processor 141, a memory 143, an artificial intelligence (AI) accelerator 145, and a hardware accelerator 147, and the at least one processor 141, the memory 143, the AI accelerator 145, and the hardware accelerator 147 may communicate with each other via a bus 149. In some implementations, the at least one processor 141, the memory 143, the AI accelerator 145, and the hardware accelerator 147 may also be included in one semiconductor chip. In addition, in some implementations, at least two of the at least one processor 141, the memory 143, the AI accelerator 145, and the hardware accelerator 147 may also be included in each of two or more semiconductor chips mounted on a board.

The at least one processor 141 may execute instructions. For example, the at least one processor 141 may also execute an operating system by executing instructions stored in the memory 143, or may also execute applications running on the operating system. In some implementations, the at least one processor 141 may instruct tasks of the AI accelerator 145 and/or the hardware accelerator 147 by executing instructions, and may also obtain a result of performing the task from the AI accelerator 145 and/or the hardware accelerator 147. In some implementations, the at least one processor 141 may include an application-specific instruction set processor (ASIP) customized for a particular use, and may also support a dedicated instruction set.

The memory 143 may have an arbitrary structure for storing data. For example, the memory 143 may also include a volatile memory device, such as dynamic RAM (DRAM) and static RAM (SRAM), or may also include a non-volatile memory device, such as flash memory and resistive RAM (RRAM). The at least one processor 141, the AI accelerator 145, and the hardware accelerator 147 may store data in the memory 143 or read the data from the memory 143 via the bus 149.

The AI accelerator 145 may indicate hardware designed for AI applications. In some implementations, the AI accelerator 145 may include an NPU for implementing a neuromorphic structure, may generate output data by processing input data provided by the at least one processor 141 and/or the hardware accelerator 147, and may provide output data to the at least one processor 141 and/or the hardware accelerator 147. In some implementations, the AI accelerator 145 may be programmable, and may be programmed by the at least one processor 141 and/or the hardware accelerator 147.

The hardware accelerator 147 may indicate hardware designed to perform a particular task at a high speed. For example, the hardware accelerator 147 may be designed to perform data transform at a high speed, such as demodulation, modulation, encoding, and decryption. The hardware accelerator 147 may be programmable, and may be programmed by at least one processor 141 and/or the hardware accelerator 147.

In some implementations, the AI accelerator 145 may execute the machine learning models described above with reference to diagrams. For example, the AI accelerator 145 may execute each of layers included in the machine learning model described above. The AI accelerator 145 may generate an output including useful information by processing input parameters, feature maps, etc. In addition, in some implementations, at least some of the models executed by the AI accelerator 145 may be executed by the at least one processor 141 and/or the hardware accelerator 147.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various change in form and details may be made therein without departing from the spirit and scope of the following claims.

1. A method of chemical mechanical polishing a wafer, the method comprising:
providing, using at least one computing device and to a first model, recipe data defining a recipe, the first model being trained by recipe samples;
obtaining, using the at least one computing device, a first removal amount from the first model;
providing, using the at least one computing device and to a second model, wafer data defining the wafer and the recipe data, the second model being trained by the recipe samples and wafer samples;
obtaining, using the at least one computing device, a second removal amount from the second model;
calculating, using the at least one computing device and based on the first removal amount and the second removal amount, an estimated removal amount of the wafer from a chemical mechanical polishing; and
performing, based on the estimated removal amount of the wafer, the chemical mechanical polishing on the wafer.

2. The method of claim 1, wherein the recipe data comprises at least one of:
pressure data defining pressure applied to the wafer;
velocity data defining a relative velocity between a pad and the wafer; or
environment data defining a process environment including slurry.

3. The method of claim 2, wherein the first model comprises an environment model trained by the recipe samples, and
wherein obtaining the first removal amount comprises:
providing the recipe data to the environment model;
obtaining an environment coefficient from the environment model; and
calculating the first removal amount based on at least one of the environment coefficient, the pressure data, or the velocity data.

4. The method of claim 3, wherein calculating the first removal amount comprises calculating the first removal amount by multiplying the environment coefficient, the pressure, and the relative velocity with each other.

5. The method of claim 3, wherein the environment model comprises an activation function that outputs a value greater than or equal to zero.

6. The method of claim 1, wherein the second model is trained based on a loss function, the loss function being based on first removal amount samples and second removal amount samples,
wherein the first model is configured to generate the first removal amount samples based on the recipe samples, and
wherein the second model is configured to generate the second removal amount samples based on the recipe samples and the wafer samples.

7. The method of claim 1, comprising
searching for a candidate recipe based on the estimated removal amount,
wherein the searching for the candidate recipe comprises:
calculating a first objective function based on a distribution of the estimated removal amount on the wafer;
calculating a second objective function based on a difference between the estimated removal amount and a target removal amount; and
deriving the candidate recipe from the first objective function and the second objective function based on an optimization algorithm.

8. The method of claim 7, wherein deriving the candidate recipe comprises applying constraints to the optimization algorithm, the constraints being defined by the estimated removal amount and the second removal amount.

9. The method of claim 7, comprising performing the chemical mechanical polishing on the wafer according to the candidate recipe.

10. A non-transitory storage medium storing instructions that, when executed by at least one processing device, cause at least one processing device to perform the method of claim 1.

11. A system for chemical mechanical polishing of a wafer according to a recipe, the system comprising:
a non-transitory storage medium configured to store instructions; and
at least one processor configured to access the non-transitory storage medium and execute the instructions to perform:
providing, to a first model, recipe data defining the recipe, the first model being trained by recipe samples;
obtaining a first removal amount from the first model;
providing, to a second model, wafer data defining the wafer and the recipe data, the second model being trained by the recipe samples and wafer samples;
obtaining a second removal amount from the second model; and
based on the first removal amount and the second removal amount, estimating a removal amount of the wafer from the polishing.

12. The system of claim 11, wherein the recipe data comprises at least one of:
pressure data defining pressure applied to the wafer;
velocity data defining a relative velocity between a pad and the wafer; or
environment data defining a process environment including slurry.

13. The system of claim 12, wherein the first model comprises an environment model trained by the recipe samples, and
wherein the at least one processor is configured to, for obtaining the first removal amount:
provide the recipe data to the environment model;
obtain an environment coefficient from the environment model; and
based on at least one of the environment coefficient, the pressure data, or the velocity data, calculate the first removal amount.

14. The system of claim 13, wherein the at least one processor is configured to, for calculating the first removal amount, calculate the first removal amount by multiplying the environment coefficient, the pressure, and the relative velocity with each other.

15. (canceled)

16. The system of claim 11, wherein the second model is trained based on a loss function that is based on first removal amount samples and second removal amount samples,
wherein the first model is configured to generate the first removal amount samples based on the recipe samples, and
wherein the second model is configured to generate the second removal amount samples based on the recipe samples and the wafer samples.

17. The system of claim 11, wherein the at least one processor is further configured to search for a candidate recipe based on the estimated removal amount, and
wherein the at least one processor is configured to, for searching for the candidate recipe:
calculate a first objective function based on a distribution of the estimated removal amount on a wafer;
calculate a second objective function based on a difference between the estimated removal amount and a target removal amount; and
derive the candidate recipe from the first objective function and the second objective function based on an optimization algorithm.

18. (canceled)

19. A method of chemical mechanical polishing of a wafer, the method comprising:
obtaining a recipe sample, a wafer sample, and a removal amount sample;
training a first model based on the recipe sample and the removal amount sample;
training a second model based on the recipe sample, the wafer sample, the removal amount sample, and a first removal amount sample generated by the trained first model,
wherein the second model is trained such that a sum of the first removal amount generated by the trained first model and a second removal amount generated by the second model corresponds to the removal amount sample;
determining a recipe based on the trained first model and the trained second model; and
performing, based on the recipe, the chemical mechanical polishing on the wafer.

20. The method of claim 19, wherein the recipe sample comprises at least one of:
a pressure sample defining pressure applied to the wafer;
a velocity sample defining a relative velocity between a pad and the wafer; or
an environment sample defining a process environment including slurry.

21. The method of claim 20, wherein training the first model comprises:
providing the recipe sample to an environment model;
obtaining an environment coefficient sample from the environment model; and
training the environment model such that a multiplication of the environment coefficient sample, the pressure sample, and the velocity sample with each other corresponds to the removal amount sample.

22. The method of claim 19, wherein training the second model comprises:
providing the recipe sample to the trained first model;
generating the first removal amount sample from the trained first model;
providing the recipe sample and the wafer sample to the second model; and
training the second model such that a sum of the first removal amount sample generated by the first model and the second removal amount sample generated by the second model corresponds to the removal amount sample.
